(19) United States
(12) Patent Application Publication
(10) Pub. No.: US 2004/0217442 A1
(43) Pub. Date: Nov. 4, 2004

(54) Semiconductor device

(76) Inventor: Hiroshi Miyagi, Niigata (JP)

Correspondence Address: DELLETT AND WALTERS, P. O. BOX 2786, PORTLAND, OR, 97208-2786, US

(21) Appl. No.: 10/484,594

(22) PCT Filed: Jun. 28, 2002
(86) PCT No.: PCT/JP02/06554

(30) Foreign Application Priority Data
Jul. 30, 2001 (JP) 2001-229648

(51) Int. Cl. H01L 29/00

(52) U.S. Cl. 257/531; 257/532

(57) ABSTRACT

A semiconductor device in which noise appearing at a terminal provided on a semiconductor substrate is reduced. The semiconductor device 10 comprises a rectangular semiconductor substrate 11, constituent component 12 disposed on the semiconductor substrate 11, and terminals 22 including a power supply terminal 20 and a ground terminal both disposed along the periphery of the semiconductor substrate 11. The constituent components 12 include a bypass capacitor 14, one end of which is connected to the power supply terminal 20 and the other of which is connected to the ground terminal 22. An inductive component 30 is provided outside of the semiconductor substrate 11. One end of the inductive component 30 is connected to the power supply terminal 20, and the other end is connected to a power supply circuit 40.

### TECHNICAL FIELD

The present invention relates to a semiconductor device formed on a semiconductor substrate.

### BACKGROUND ART

A bypass capacitor is conventionally used to reduce noise superimposed on and propagated through a power line or the like. For example, by connecting an externally attached bypass capacitor to a power terminal of an IC, it is possible to reduce noise outputted by the IC and superimposed on the power line.

Furthermore, progress has recently been made on the research of techniques of integrally forming various circuits on a semiconductor substrate using a semiconductor process such as a MOS process. These techniques have already been put to practical use in some devices. When the semiconductor process is used to form various circuits on one chip, the size and cost of the whole device can be reduced. Accordingly, the range of circuits formed on one chip is expected to be increased in the future.

If the constituent components of a circuit including a bypass capacitor are formed on a semiconductor substrate, it is disadvantageously impossible to sufficiently reduce noise appearing at a terminal to which the bypass capacitor is connected. This is because it is impossible to increase the electrostatic capacity of the bypass capacitor formed on the semiconductor substrate.

### DISCLOSURE OF THE INVENTION

The present invention is created in view of this point. It is an object of the present invention to provide a semiconductor device that can reduce noise appearing at a terminal formed on a semiconductor substrate.

To accomplish this object, a semiconductor device according to the present invention comprises a constituent component formed on a semiconductor substrate, a terminal disposed on the semiconductor substrate and connected to the constituent component, a bypass capacitor formed on the semiconductor substrate and connected to the terminal, and an inductive component provided outside the semiconductor substrate and connected to the terminal. The inductive component externally connected to the semiconductor substrate can be used to sufficiently reduce noise outputted by the terminal, by absorbing and converting it into heat, the noise being outputted without being sufficiently reduced because of the small electrostatic capacity of the bypass capacitor, formed on the semiconductor substrate.

Furthermore, the terminal is desirably a power supply terminal. Thus, noise generated inside the semiconductor device can be prevented from flowing into an external circuit through a power supply line connected to the power supply terminal.

Alternatively, the terminal is desirably a clock terminal. Thus, noise generated inside the semiconductor device can be prevented from flowing into an external circuit through a clock line connected to the clock terminal.

Alternatively, the terminal is desirably a ground terminal. Thus, noise generated inside the semiconductor device can be prevented from flowing into an external circuit through a ground line connected to the ground terminal or a ground layer.

Moreover, the above inductive component is desirably a magnetic material component such as a ferrite bead or a ferrite core which is arranged in close contact with the periphery of a line connected to the terminals. By closely contacting the magnetic material component with the periphery of the line, the inductance of the line can be increased. Accordingly, the inductive component can be easily formed. Furthermore, the above inductive component is desirably an inductor inserted into the line connected to the terminal. This enables noise to be easily reduced using the inductive component.

### BRIEF DESCRIPTION OF THE DRAWINGS

FIG. 1 is a diagram showing a semiconductor device according to an embodiment;

FIG. 2 is a diagram showing a specific example of an inductive component;

FIG. 3 is a diagram showing a specific example of an inductive component;

FIG. 4 is a diagram showing a specific example of an inductive component;

FIG. 5 is a diagram showing a variation of the semiconductor device; and

FIG. 6 is a diagram showing another variation of the semiconductor device.

### BEST MODE FOR CARRYING OUT THE INVENTION

A detailed description will be given below of a semiconductor device according to an embodiment to which the present invention is applied.

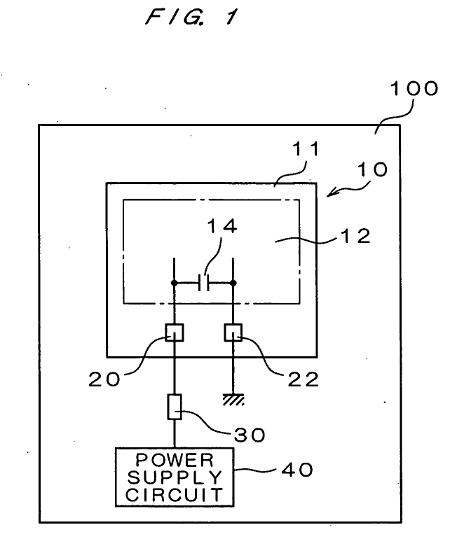

FIG. 1 is a diagram showing a semiconductor device according to the present embodiment. As shown in FIG. 1, the semiconductor device 10 according to the present embodiment includes a rectangular semiconductor substrate 11, a constituent component 12 formed on the semiconductor substrate 11 using a semiconductor process such as a MOS process, and terminals including a power supply terminal 20 and a ground terminals 22 both formed near the periphery of the semiconductor substrate 11.

The constituent component 12 forms a circuit constituting, for example, a receiver. Furthermore, the constituent component 12 includes a bypass capacitor 14. One end of the bypass capacitor 14 is connected to the power supply terminal 20. The other end of the bypass capacitor 14 is connected to the ground terminals 22. There is provided outside the semiconductor substrate 11, an inductive component 30 with one end thereof connected to the power supply terminal 20 and the other end thereof connected to the power supply circuit 40.

The above semiconductor device 10, inductive component 30, and power supply circuit 40 are each mounted on a surface of a wiring board 100.

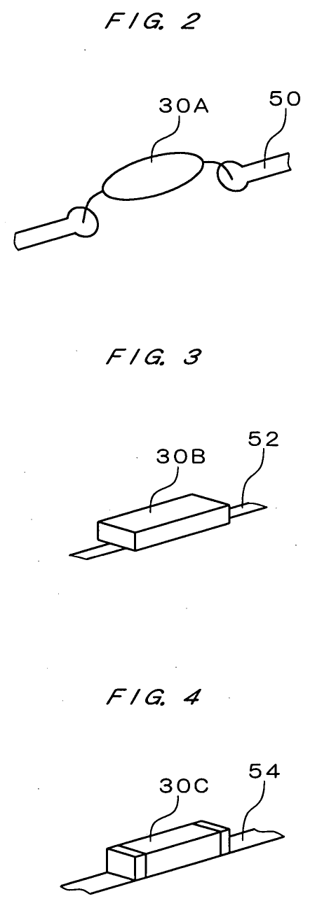

FIGS. 2 to 4 are diagrams showing specific examples of the inductive component.

FIG. 2 is a perspective view showing an example in which a ferrite bead 30 A is mounted in the device. As shown in FIG. 2, a component is provided in the middle of a line 50 connecting the power supply terminal 20 and the power supply circuit 40 together; the component comprises a ferrite bead 30 A integrally arranged in close contact with the leads. This arrangement increases the inductance of the leads formed with the ferrite bead 30A.

FIG. 3 is a diagram showing an example in which a ferrite core 30B is mounted in the device. As shown in FIG. 3, the ferrite core 30B is arranged on a part of a line 52 in close contact with it, the line 52 connecting the power supply terminal 20 and the power supply circuit 40 together. This arrangement partly increases the inductance of the line 52, running under the ferrite core 30B.

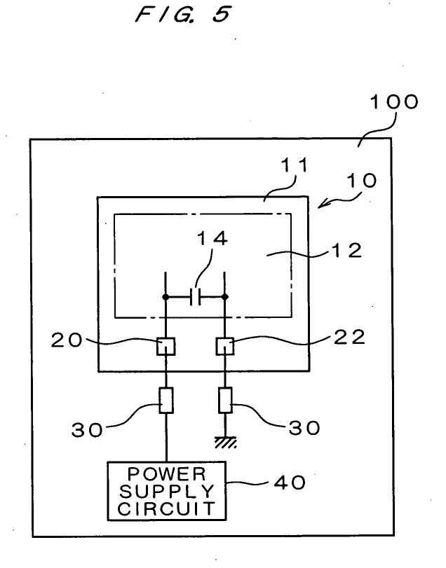

FIG. 4 is a diagram showing an example in which a chip inductor 30C is mounted in the device. As shown in FIG. 4, the chip inductor 30C is inserted, as a surface mounting component, into the middle of a line 54 connecting the power supply terminal 20 and the power supply circuit 40 together.

As described above, in the semiconductor device 10 according to the present embodiment, the bypass capacitor 14, connected between the power supply terminal 20 and the ground terminal 22, is formed on the semiconductor substrate 11. Furthermore, the inductive component 30 using the above described ferrite bead 30A, ferrite core 30B, chip inductor 30C, or the like is connected to the power supply terminal 20 outside the semiconductor substrate 11 as an externally attached component.

Provided that the bypass capacitor 14, formed on the semiconductor substrate 11, has a practical area, it cannot provide a large electrostatic capacity. Thus, if loud noise occurs in the constituent component 12, it cannot be sufficiently reduced using only the bypass capacitor 14. However, in the semiconductor device 10 according to the present embodiment, the inductive component 30 is connected between the power supply terminal 20 and the power supply circuit 40. Accordingly, the inductive component 30 can reliably reduce noise which is outputted to the power supply line, connected to the power supply terminal 20, and which cannot sufficiently be reduced using only the bypass capacitor 14.

The present invention is not limited to the above described embodiment. Many variations may be made to the embodiment without departing from the spirits of the present invention. For example, in the above described embodiment, the inductive component 30 is connected only to the power supply terminal 20. However, as shown in FIG. 5, separate inductive components 30 may be connected to the power supply terminal 20 and the ground terminal 22, respectively. This arrangement reduces noise outputted to the power supply line, connected to the power supply terminal 20, and to a ground line or layer connected to the ground terminal 22.

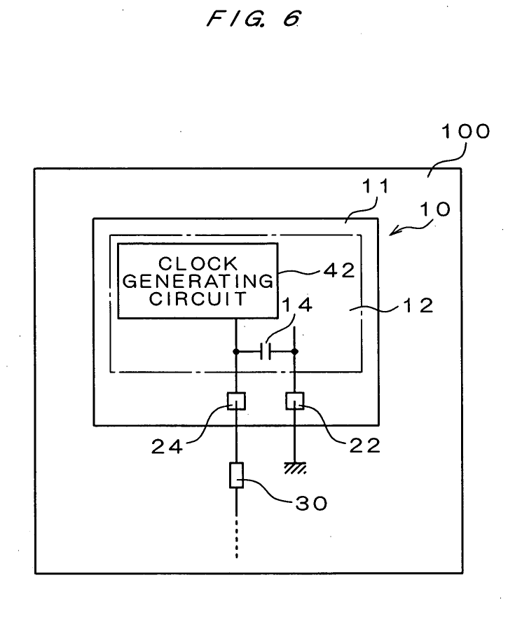

Furthermore, in the above described embodiment, the focus is on the power supply terminal 20. However, noise outputted by other terminals may be reduced. FIG. 6 is a diagram showing the configuration of a semiconductor device that reduces noise outputted to a clock line. As shown in FIG. 6, if a clock terminal 24 is connected to a clock generating circuit 42 formed by the constituent component 12, both bypass capacitor 14 and inductive component 30 may be connected to the clock terminal 24. This arrangement enables a reduction in noise outputted to the clock line by the clock terminal 24.

### INDUSTRIAL APPLICABILITY

As described above, according to the present invention, noise outputted by the terminal can be sufficiently reduced by allowing the inductive component, externally connected to the semiconductor substrate, to absorb and convert it into heat, the noise being outputted without being sufficiently reduced because of the small electrostatic capacity of the bypass capacitor, formed on the semiconductor substrate.

1. A semiconductor device comprising:
a constituent component formed on a semiconductor substrate;
a terminal disposed on said semiconductor substrate and connected to said constituent component;
a bypass capacitor formed on the semiconductor substrate and connected to said terminal; and
an inductive component provided outside said semiconductor substrate and connected to said terminal.

2. The semiconductor device according to claim 1, wherein said terminal is a power supply terminal.

3. The semiconductor device according to claim 1, wherein said terminal is a clock terminal.

4. The semiconductor device according to claim 1, wherein said terminal is a ground terminal.

5. The semiconductor device according to claim 1, wherein said inductive component is a magnetic material component which is arranged in close contact with the periphery of a line connected to the terminal.

6. The semiconductor device according to claim 5, wherein said magnetic material component is a ferrite bead.

7. The semiconductor device according to claim 5, wherein said magnetic material component is a ferrite core.

8. The semiconductor device according to claim 1, wherein said inductive component is an inductor inserted into the line connected to said terminal.
